(19) United States
(12) Patent Application Publication
(10) Pub. No.: US 2012/0100650 A1
(43) Pub. Date: Apr. 26, 2012

(54) VICINAL SEMIPOLAR III-NITRIDE SUBSTRATES TO COMPENSATE TILT OF RELAXED HETERO-EPITAXIAL LAYERS

(75) Inventors: James S. Speck, Goleta, CA (US); Anurag Tyagi, Goleta, CA (US); Alexey E. Romanov, St. Petersburg (RU); Shuji Nakamura, Santa Barbara, CA (US); Steven P. DenBaars, Goleta, CA (US)

(73) Assignee: THE REGENTS OF THE UNIVERSITY OF CALIFORNIA, Oakland, CA (US)

(21) Appl. No.: 13/281,767

(22) Filed: Oct. 26, 2011

Related U.S. Application Data
(60) Provisional application No. 61/406,899, filed on Oct. 26, 2010.

(51) Int. Cl. H01L 29/20; H01S 5/026; H01L 33/06; H01L 21/20; H01L 33/30

(52) U.S. Cl. 438/31; 438/478; 257/201; 257/13; 372/45.01; 257/E33.023; 257/E21.09; 257/E29.089

(57) ABSTRACT

A method for fabricating a semi-polar III-nitride substrate for semi-polar III-nitride device layers, comprising providing a vicinal surface of the III-nitride substrate, so that growth of relaxed heteroepitaxial III-nitride device layers on the vicinal surface compensates for epilayer tilt of the III-nitride device layers caused by one or more misfit dislocations at one or more heterointerfaces between the device layers.

### CROSS-REFERENCE TO RELATED APPLICATIONS

This application claims the benefit under 35 U.S.C. Section 119(e) of co-pending and commonly-assigned U.S. Provisional Application Ser. No. 61/406,899 filed on Oct. 26, 2010, by James S. Speck, Anurag Tyagi, Alexey E. Romanov, Shuji Nakamura, and Steven P. DenBaars, entitled “VICINAL SEMIPOLAR III-NITRIDE SUBSTRATES TO COMPENSATE TILT OF RELAXED HETERO-EPITAXIAL LAYERS,” attorney's docket number 30794.386-US-P1 (2010-973), which application is incorporated by reference herein.

This application is related to the following co-pending and commonly-assigned U.S. patent applications:

U.S. Utility patent application Ser. No. 12/716,176, filed Mar. 2, 2010, by Robert M. Farrell, Michael Iza, James S. Speck, Steven P. DenBaars and Shuji Nakamura, entitled “METHOD OF IMPROVING SURFACE MORPHOLOGY OF (Ga,Al,In,B)N THIN FILMS AND DEVICES GROWN ON NON POLAR OR SEMIPOLAR (Ga,Al,In,B)N SUBSTRATES,” attorney' docket number 30794.306-US-U1 (2009-429), which application claims the benefit under 35 U.S.C. Section 119(e) of:

U.S. Provisional Patent Application Ser. No. 61/156,710, filed on Mar. 2, 2009, by Robert M. Farrell, Michael Iza, James S. Speck, Steven P. DenBaars, and Shuji Nakamura, entitled “METHOD OF IMPROVING SURFACE MORPHOLOGY OF (Ga,Al,In,B)N THIN FILMS AND DEVICES GROWN ON NONPOLAR OR SEMIPOLAR (Ga,Al,In,B)N SUBSTRATES,” attorney's docket number 30794.306-US-P1 (2009-429-1); and

U.S. Provisional Patent Application Ser. No. 61/184,535, filed on Jun. 5, 2009, by Robert M. Farrell, Michael Iza, James S. Speck, Steven P. DenBaars, and Shuji Nakamura, entitled “METHOD OF IMPROVING SURFACE MORPHOLOGY OF (Ga,Al,In,B)N THIN FILMS AND DEVICES GROWN ON NONPOLAR OR SEMIPOLAR (Ga,Al,In,B)N SUBSTRATES,” attorney's docket number 30794.306-US-P2 (2009-429-2); and

U.S. Utility patent application Ser. No. ______, filed on same date herewith, by James S. Speck, Anurag Tyagi, Steven P. DenBaars, and Shuji Nakamura, entitled “LIMITING STRAIN RELAXATION IN III-NITRIDE HETEROSTRUCTURES BY SUBSTRATE AND EPITAXIAL LAYER PATTERING,” attorney' docket number 30794.387-US-U1 (2010-804), which application claims the benefit under 35 U.S.C. Section 119(e) of co-pending and commonly-assigned U.S. Provisional Patent Application Ser. No. 61/406,876 filed on Oct. 26, 2010, by James S. Speck, Anurag Tyagi, Steven P. DenBaars, and Shuji Nakamura, entitled “LIMITING STRAIN RELAXATION IN III-NITRIDE HETEROSTRUCTURES BY SUBSTRATE AND EPITAXIAL LAYER PATTERNING,” attorney' docket number 30794.387-US-P1 (2010-804); and

U.S. Utility patent application Ser. No. 13/041,120 filed on Mar. 4, 2011, by Po Shan Hsu, Kathryn M. Kelchner, Robert M. Farrell, Daniel Haeger, Hiroaki Ohta, Anurag Tyagi, Shuji Nakamura, Steven P. DenBaars, and James S. Speck, entitled “SEMI-POLAR III-NITRIDE OPTOELECTRONIC DEVICES ON M-PLANE SUBSTRATES WITH MISCUTS LESS THAN+/−15 DEGREES IN THE C-DIRECTION,” attorney's docket number 30794.366-US-U1 (2010-543-1), which application claims the benefit under 35 U.S.C. Section 119(e) of co-pending and commonly assigned U.S. Provisional Patent Application Ser. No. 61/310,638 filed on Mar. 4, 2010 by Po Shan Hsu, Kathryn M. Kelchner, Robert M. Farrell, Daniel Haeger, Hiroaki Ohta, Anurag Tyagi, Shuji Nakamura, Steven P. DenBaars, and James S. Speck, entitled “SEMI-POLAR III-NITRIDE OPTOELECTRONIC DEVICES ON M-PLANE SUBSTRATES WITH MISCUTS LESS THAN+/−15 DEGREES IN THE C-DIRECTION,” attorney's docket number 30794.366-US-P1 (2010-543-1);

which applications are incorporated by reference herein.

### STATEMENT REGARDING FEDERALLY SPONSORED RESEARCH AND DEVELOPMENT

This invention was made with Government support under Grant No. FA8718-08-0005 awarded by DARPA-VIGIL. The Government has certain rights in this invention.

### BACKGROUND OF THE INVENTION

1. Field of the Invention

This invention relates to a method of fabricating improved III-nitride substrates.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

In spite of numerous advantages offered by growth of optoelectronic devices on nonpolar/semipolar III-nitride substrates, due to the unusual surface morphologies that are typically observed for III-nitride thin films grown on nonpolar or semipolar substrates [2-4], it will be difficult for device manufacturers to fully realize the expected inherent advantages.

This invention describes a method for controlling the surface morphology of III-nitride thin films on semipolar substrates.

### SUMMARY OF THE INVENTION

Recently, semipolar III-nitride based Light Emitting Diodes (LEDs) and Laser Diodes (LDs) have attracted significant attention, especially for long wavelength optoelectronic devices. However, one issue relevant to heteroepitaxy of semipolar (Al,In,Ga)N layers is the possibility of stress-relaxation via misfit dislocation (MD) formation, which is attributed to glide of pre-existing threading dislocations (TDs) on the basal (0001) plane under the influence of shear stress [1,2]. One consequence of MD formation at the hetero-interfaces is the concomitant macroscopic tilt of the relaxed epilayers. This tilt can alter the vicinality of the epilayer surface which affects the surface morphology of growing epilayers, and has significant device implications. By intentional substrate miscut, the present invention can compensate the change in vicinality due to the induced epilayer tilt, and thus control the surface morphology and device performance.

To overcome the limitations in the prior art described above, and to overcome other limitations that will become apparent upon reading and understanding the present specification, the present invention describes a method for fabricating a semi-polar III-nitride substrate for semi-polar III-nitride device layers, comprising providing a vicinal surface of a substrate, wherein growth of device layers on the vicinal surface compensates for epilayer tilt of the device layers caused by one or more misfit dislocations at one or more heterointerfaces with the device layers, the substrate is a semi-polar III-nitride substrate, the device layers are semi-polar III-nitride layers, and the device layers are relaxed heteroepitaxial layers.

An orientation of the vicinal surface can partially or fully compensate for the epilayer tilt. The epilayer tilt caused by the misfit dislocations can be at least 0.5 degrees.

The method can further comprise growing the device layers on the vicinal surface, wherein an orientation of the vicinal surface is such the device layers grow in a planar growth mode on the vicinal surface, resulting in a planar top surface of the device layers. The vicinal surface can be such that the top surface has a surface roughness of 0.4 nanometers or less over an area of at least 5 micrometers by 5 micrometers of the top surface. An orientation of the vicinal surface can remove, minimize, or reduce slip related, or shear stress related, features from a top surface of the device layers.

The device layers can be thicker and higher composition alloy epilayers as compared to semi-polar III-nitride device layers that are grown on an on-axis surface of the semi-polar III-nitride substrate, or as compared to semi-polar III-nitride device layers that are grown on a different vicinal surface of the semi-polar III-nitride substrate.

The device layers can form a semi-polar III-nitride light emitting device structure, wherein the device layers include one or more indium containing light emitting active layers that emit light having a peak intensity at a wavelength in a green wavelength range or longer, or emit light having a peak intensity at a wavelength of 500 nm or longer.

The semi-polar III-nitride light emitting device structure can comprise a Light Emitting Diode (LED) or Laser Diode (LD) device structure. The device layers can further include waveguiding and/or cladding layers that are sufficiently thick, and have a composition, to function as waveguiding layers for the light emitted by the active layers of the LD or LED.

The active layers and waveguiding layers can comprise one or more InGaN quantum wells with GaN barrier layers, and the cladding layers can comprise one or more periods of alternating AlGaN and GaN layers.

The vicinal surface can be such that a top surface of the semi-polar III-nitride light emitting device structure emits the light with an emission that is uniform over an area of the top surface of at least 20 micrometers by 20 micrometers.

One or more of the device layers can be heterostructures, or lattice mismatched with another of the device layers or the substrate, or comprise a different composition from another of the device layers or the substrate.

One or more of the device layers can have a thickness and/or composition that is high enough such that a film, comprising the device layers, has a thickness near or greater than the film's critical thickness for relaxation. The device layers can comprise layers that are non-coherently grown, or that are partially or fully relaxed.

The vicinal surface can be oriented or miscut, with respect an on-axis semi-polar plane of the substrate, along a direction of one or more slip planes of the device layers, so as to counter or reduce the epilayer tilt caused by the slip planes.

The vicinal surface can be oriented or miscut at an angle with respect to an on-axis semipolar plane of the substrate, and towards a c+ or c− direction of the substrate, wherein the angle (e.g., 5 degrees or less) is sufficiently small that the device layers grown on the substrate have a semipolar property that is characteristic of the semi-polar plane of the substrate.

The substrate can be bulk III-nitride or a film of III-nitride. The substrate can comprise 10⁶ cm⁻² or more threading dislocations.

The present invention further discloses a semi-polar III-nitride substrate for a semipolar optoelectronic or electronic device, comprising a vicinal surface of a substrate, wherein growth of device layers on the vicinal surface compensates for epilayer tilt of the device layers caused by one or more misfit dislocations at one or more heterointerfaces with or between the device layers, the substrate is a semi-polar III-nitride substrate, the device layers are semi-polar III-nitride layers, and the device layers are relaxed heteroepitaxial layers.

The present invention further discloses optoelectronic or electronic devices grown on the substrate, including a light emitting diode, a transistor, a solar cell, or a laser diode.

### BRIEF DESCRIPTION OF THE DRAWINGS

Referring now to the drawings in which like reference numbers represent corresponding parts throughout:

FIG. 1, taken from [2], illustrates schematics of misfit dislocations in semipolar (11-22) (In,Al)GaN/GaN heterostructures, wherein (a) is a perspective view of an AlGaN or InGaN epilayer grown on semipolar GaN, showing geometry of misfit and threading dislocations segments lying in the (0001) glide plane, where possible dislocation Burgers vectors a₁, a₂, a₃ are indicated, and (b) is a [1-100] cross-sectional schematic showing an array of edge misfit dislocations, and decomposition of their Burger vector into parallel lattice misfit compensating and perpendicular components, and where the magnitude of the lattice tilt angle α is exaggerated.

FIG. 2 (taken from [1]) illustrates High Resolution X-ray Diffraction reciprocal space mapping (HRXRD RSM) around the symmetric (11-22) GaN reflection for a full LD structure, wherein the in-plane projection of the X-ray beam was aligned parallel to (a) [1-100] and (b) [-1-123], respectively.

FIG. 3 shows the surface morphology and emission uniformity for blue light emitting LDs grown on a (20-21) GaN substrate (co-loaded growth), wherein in (a) the substrate has a miscut with an angle of −0.1297° with respect to the c-projection and an angle of 0.1943° towards the a-direction, and in (b) the substrate has a miscut with an angle of 0.2178° with respect to the c-projection and an angle of 0.4053° towards the a-direction, and the miscut angles were measured via glancing angle X-ray Diffraction (XRD).

FIG. 4 shows a schematic illustrating a vicinal surface of a substrate according to one or more embodiments of the present invention, illustrating the surface normal of the vicinal surface, the GaN [0001] toward miscut, the miscut direction, and the plane normal of the semipolar plane (direction normal to the semipolar plane) of the substrate.

FIG. 5 is a flowchart illustrating a method of the present invention.

FIG. 6 is a flowchart illustrating another method of the present invention.

FIG. 7 is a cross-sectional schematic of a semi-polar III-nitride light emitting device structure.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes a method for controlling the surface morphology of III-nitride thin films on semipolar substrates. Improved surface morphology can lead to a number of advantages for semipolar nitride device manufacturers, including, but not limited to, better uniformity in the thickness, composition, doping, electrical properties, and luminescence characteristics of individual layers in a given device. Therefore, the present invention enables the realization of the benefits of semipolar nitride LEDs and diode lasers.

More specifically, a purpose of this invention is to generate nitride LEDs and diode lasers with improved manufacturability and high performance. The proposed devices can be used as an optical source for various commercial, industrial, or scientific applications. These nonpolar or semipolar nitride LEDs and diode lasers are expected to find utility in the same applications as c-plane nitride LEDs and diode lasers. These applications include solid-state projection displays, high resolution printers, high density optical data storage systems, next generation DVD players, high efficiency solid-state lighting, optical sensing applications, and medical applications.

The present invention discloses the calculated expected value of lattice tilt for partially relaxed semipolar AlGaN/InGaN films, which leads to the realization that epitaxial layer vicinality can be significantly altered due to plastic relaxation.

Nomenclature

GaN and its ternary and quaternary compounds incorporating aluminum and indium (AlGaN, InGaN, AlInGaN) are commonly referred to using the terms (Al,Ga,In)N, III-nitride, Group III-nitride, nitride, Al_{(1-x-y)}In_{y}GaₓN where 0<x<1 and 0<y<1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaIN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials. Boron (B) may also be included.

The term “AlₓGa₁₋ₓN-cladding-free” refers to the absence of waveguide cladding layers containing any mole fraction of Al, such as AlₓGa₁₋ₓN/GaN superlattices, bulk AlₓGa₁₋ₓN, or AlN. Other layers not used for optical guiding may contain some quantity of Al (e.g., less than 10% Al content). For example, an AlₓGa₁₋ₓN electron blocking layer may be present.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero 1 Miller index.

Technical Description

State of the art commercial III-nitride devices are based on coherent growth of hetero-epitaxial films on III-nitride substrate. For the case of coherent growth of heteroepitaxial III-nitride on a (hkil)-oriented semipolar III-nitride substrate, the (hkil) crystal planes of the film are parallel to those of the substrate, i.e. no macroscopic tilt of the epilayer is observed.

However, if the heteroepitaxial layers are partially/fully relaxed via Misfit Dislocation (MDs) at the heterointerfaces, a concomitant tilt of those epilayers is observed. This tilt can alter the vicinality of the epilayer and significantly affect surface morphology, especially regarding planarity and uniformity.

To illustrate the background and concept, growth of (Al,In,Ga)N heteroepitaxial layers on a specific semipolar GaN substrate, (11-22), is described. However, the concept and invention pertain to thin film growth on any semipolar III-nitride substrates.

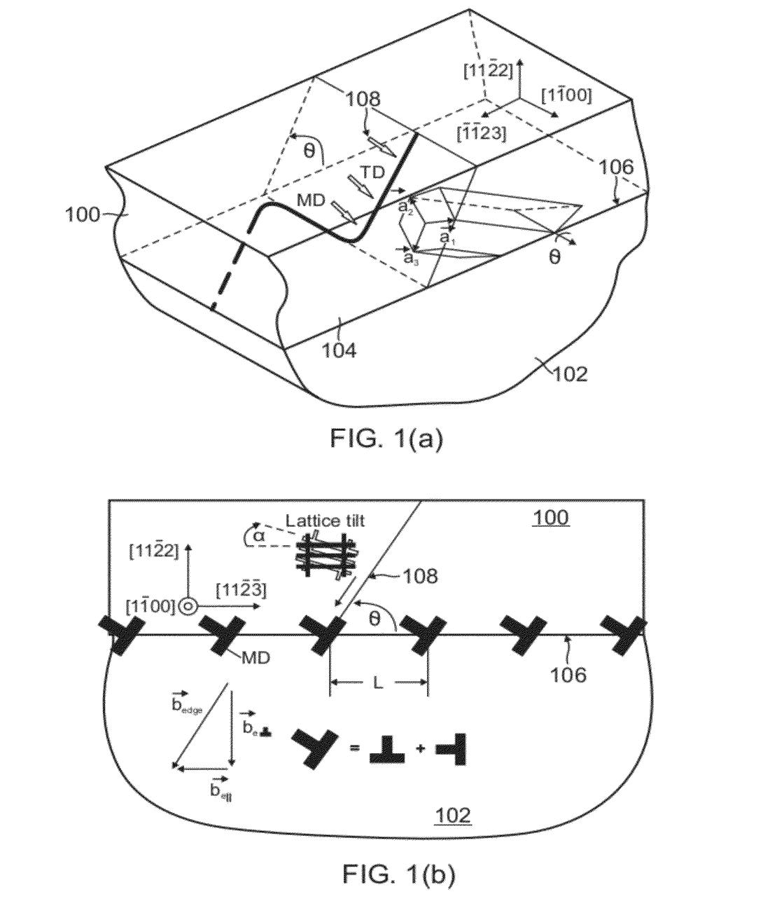

FIG. 1(a) shows a perspective schematic depicting MD formation via glide of pre-existing TDs in the inclined (0001) basal plane, in an (Al,In)GaN epilayer 100 grown on a 11-22 GaN substrate 102 having a top surface that is a semi-polar 11-22 plane 104. Pure edge MDs, with Burgers vector parallel to a₃, can form at the heterointerface 106 to relieve lattice misfit stress. The dislocation glide plane 108 (the (0001) c-plane), the angle θ of the semi-polar plane 104 with respect to the (0001) c-plane, dislocation Burgers vectors a₁ and a₂, and the 11-22, 1-100, and -1-123 directions are also shown.

As shown in FIG. 1(b), the Burgers vector b_{edge} can be decomposed into two components, parallel (b_{e∥})(lattice misfit compensating), and perpendicular (b_{e⊥})tilt-inducing), to the hetero-interface 106. The line direction of the MDs is parallel to the in-plane m-axis [1-100]. Since (0001) is the only slip plane, the plastic relaxation is associated with tilt of the epitaxial (Al,In)GaN layers 100. The epilayer tilt angle α can be measured via high-resolution X-ray diffraction. Also shown in FIG. 1(b) is the separation L of the MDs.

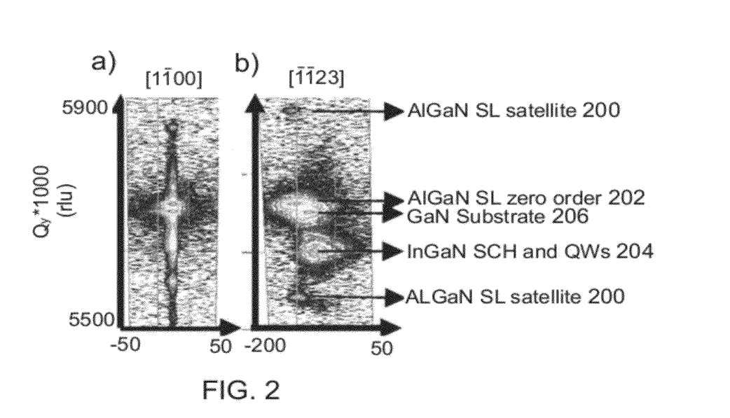

FIGS. 2 (a) and (b) show high resolution x-ray diffraction (HR-XRD) RSM around the symmetric 11-22 GaN reflection for a full (11-22) LD structure [1] (100 nm p-GaN/p-GaN/AlGaN superlattice/p-GaN/p-InGaN waveguiding layer/p-AlGaN electron blocking layer/2 period InGaN Quantum Well/GaN barrier/n-InGaN waveguiding layer/n-GaN spacer/n-AlGaN/GaN Short Period Superlattice (SPSL) cladding layer/2 μm HT GaN). The in-plane projection of the x-ray beam was aligned with [1-100], as shown in FIG. 2(a), and [-1-123], as shown in FIG. 2(b), respectively.

In FIG. 2(b), the peaks corresponding to the AlGaN cladding layers (AlGaN Superlattice (SL) peak 200 and AlGaN SL zero order peak 202) and the InGaN layers (InGaN waveguiding or separate confinement heterostructure (SCH) layers and InGaN quantum well (QW) peak 204) are misaligned with the GaN substrate peak 206—i.e., the successive epitaxial layers are tilted. The tilt occurs about [1-100], indicating that vicinality towards the c-axis is affected. For a tensile epilayer, e.g., AlGaN on GaN, the MDs will all have the same sense of additional half plane (in this case, in the tensile layer). Since slip occurs on the inclined (0001) plane, stress relief is provided by the edge component of the MDs, b_{edge,∥} (Burgers vector edge component parallel to the film/substrate interface), and the tilt is caused by the normal component of the Burgers vector b_{edge,⊥} (Burgers vector edge component normal to the interface).

A simple estimate for the epilayer tilt is α=b_{edge,⊥} divided by MD spacing=b_{edge,⊥}·ρ_{MD}, where b_{edge,⊥}=b sin θ (where θ is the inclination angle of the (11-22) plane with respect to the (0001) plane) and ρ_{MD} is the misfit dislocation density. Also, since the tilt is proportional to b_{edge,⊥}, semipolar planes with high inclination angles (i.e., >60°) with respect to the c-plane, e.g. (20-21), (30-31) etc., would have higher cumulative tilt for a given MD density. Tilt angles as large as 0.66° have previously been reported [2].

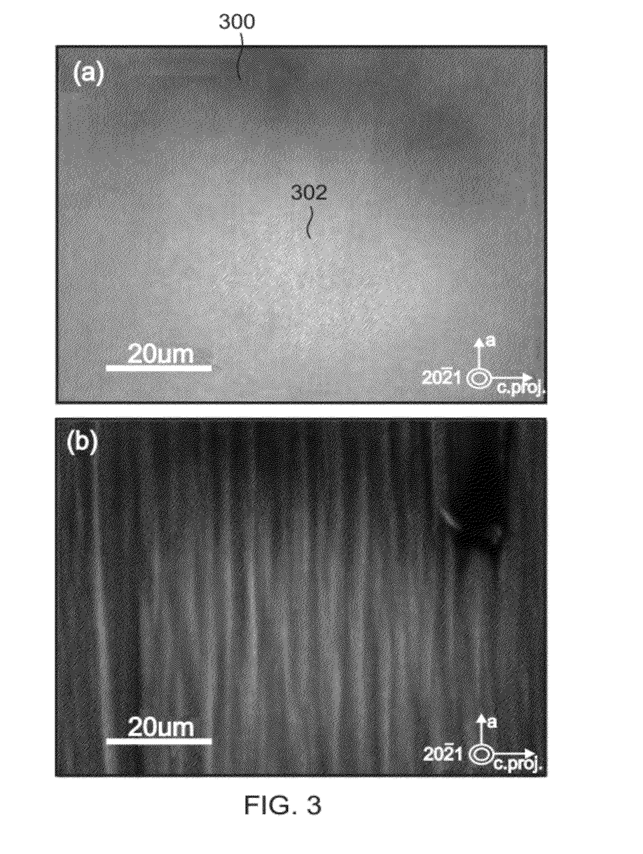

The impact of substrate miscut on the morphology of m-plane GaN has also been reported, underscoring the importance of controlling miscut. The effect of substrate miscut (towards c-direction) on surface morphology and emission uniformity for a LD structure grown on (20-21) GaN is shown in FIGS. 3(a) and 3(b). The present invention notes that a much smoother top surface 300 and uniform emission 302 is observed for the sample with lower misorientation, FIG. 3(a). In FIGS. 3(a) and 3(b), the a-direction and c-projection direction are indicated by arrows, the 20-21 direction is indicated by a dot within a circle, and the scale is 20 micrometers.

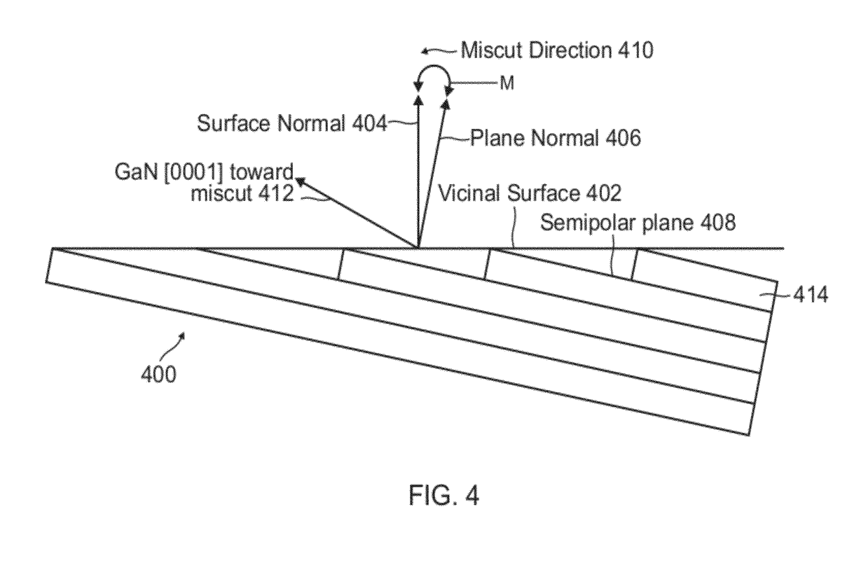

FIG. 4 shows a schematic illustrating a substrate 400 miscut (also referred to as misorientation, vicinality), resulting in a vicinal surface 402 upon which III-nitride device layers can be grown. The vicinal surface has a surface normal 404, and the vicinal surface is miscut, or oriented, such that its surface normal 404 is at an angle M with respect to the plane normal 406 of the substrate's 400 on-axis semi-polar plane 408. The miscut is in a miscut direction 410 towards the c-projection direction 412 (e.g., GaN (0001) toward miscut), and the vicinal surface 402 comprises steps 414.

Instead of slicing/polishing a substrate parallel to a crystallographic orientation, it can be sliced/polished at a small angle (<5° to provide a miscut/vicinal surface. Changing the surface vicinality alters the surface step density, and thus can significantly alter surface morphology and epitaxial growth modes, etc. As mentioned above, the lattice tilt accompanying stress-relaxation for heteroepitaxial semipolar III-nitride films occurs parallel to the in-plane projection of the c-axis. Hence, the semipolar III-nitride substrate should be miscut towards the c+/c− axis to compensate for the tilt (tensile/compressively strained films will tilt in opposite directions). The present invention can comprise slicing/polishing III-nitride semipolar substrates at a slight misorientation towards the c+/c− axis.

For example, an intentional miscut on the {20-21} plane of a substrate, to compensate tilt of a relaxed epilayer on the substrate, may be performed. For an InGaN (5% In) layer on an Al_{0.17}GaN layer on the {20-21} III-nitride semipolar substrate, the miscut was calculated to be ˜1° towards the c+/c− axis.

Process Steps

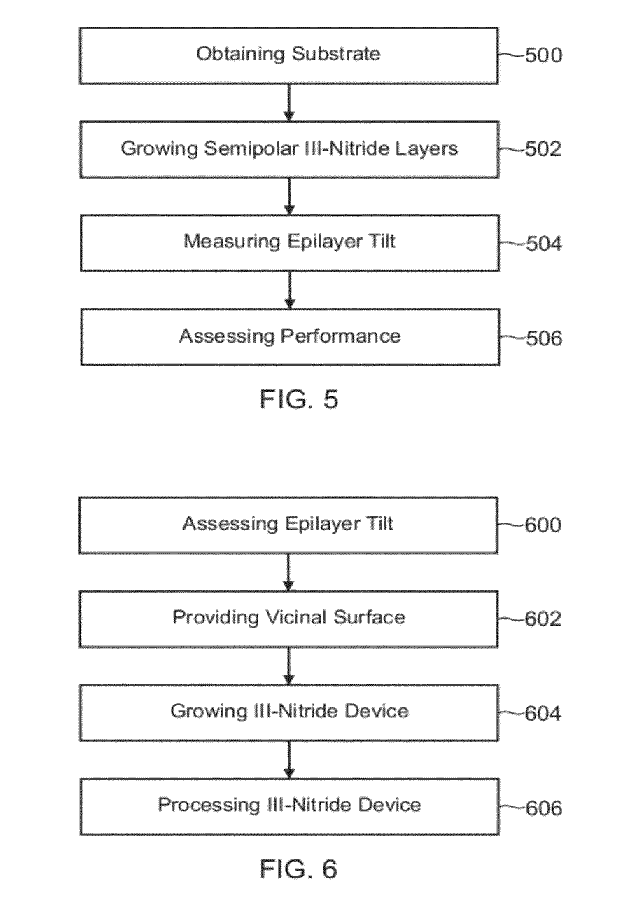

In one embodiment of the present invention, as illustrated in FIG. 5, a method for fabricating semipolar III-nitride devices and/or selecting a vicinal surface of the III-nitride semipolar substrate used to grow device layers, may comprise the following steps.

As a first step, illustrated in Block 500, semipolar III-nitride substrates with varying miscut angles (e.g., −2°-+2° towards the c-direction may be obtained (e.g., from a manufacturer such as Mitsubishi Chemical Corp.).

Block 502 illustrates the substrates may then be co-loaded for heteroepitaxial growth of partially or fully relaxed semipolar III-nitride layers.

The epilayer tilt, surface vicinality and morphology may then be measured quantitatively/qualitatively, as illustrated in Block 504.

Devices grown on various miscut (mis-oriented) substrates are then compared to assess performance, as illustrated in Block 506. The miscut that obtains the devices having the best performance can then be selected.

Accordingly, FIG. 5 illustrates a method comprising (a) growing 502 III-nitride device layers or structures (e.g, LED, LD, or transistor device structures) on III-nitride substrates having a range of miscuts 500, to obtain a plurality of device structure growths on different miscut substrates; (b) obtaining one or more of the epilayer tilt 504 and at least one device characteristic for each of the plurality of device structure growths; and (c) selecting 506 the miscut substrate having the miscut that minimizes the epilayer tilt for the III-nitride device layers or the device structure, and provides the desired/maximum device performance for the device structure.

FIG. 6 illustrates another method for fabricating a semipolar III-nitride device with improved performance, comprising selecting and providing a vicinal surface of the III-nitride semipolar substrate upon which the device is grown, wherein the vicinal surface compensates for epilayer tilt and/or improves the device performance.

Obtaining or Assessing Epilayer Tilt

Block 600 of FIG. 6 represents obtaining or assessing the epilayer tilt for semi-polar III-nitride device layers or a semi-polar device structure deposited on a substrate (e.g., a non-miscut on-axis semi-polar III-nitride substrate, such as an on-axis semi-polar GaN substrate). The substrate can be bulk III-nitride or a film of III-nitride. The substrate can comprise an initial semi-polar III-nitride (e.g., template) layer or epilayer grown on a substrate (e.g., heteroepitaxially on a foreign substrate, such as sapphire, spinel, or silicon carbide). The III-nitride substrate can comprise 10⁶ cm⁻² or more threading dislocations, for example.

The epilayer tilt can be obtained by calculation or measurement, for example. The epilayer tilt (e.g., caused by the MDs) can be at least 0.5 degrees, or 0.3 degrees to at least 0.6 degrees, for example. However the present invention is not limited to particular epilayer tilts, and smaller or larger tilts can be measured or calculated, and ultimately compensated for in the next step.

Providing The Vicinal Surface

Block 602 of FIG. 6 represents providing a vicinal surface (e.g., 402 in FIG. 4) of a substrate, wherein growth of device layers on the vicinal surface compensates for epilayer tilt of the device layers caused by one or more misfit dislocations at one or more heterointerfaces with and/or between the device layers. The substrate is typically a semi-polar III-nitride substrate, the device layers are typically semi-polar III-nitride layers, and the device layers are typically relaxed heteroepitaxial layers. The vicinal surface can compensate for the epilayer tilt. For example, the epilayer tilt can be caused by a heterointerface with an on-axis semi-polar surface of a semi-polar III-nitride substrate or with a different vicinal surface.

The substrate can be bulk III-nitride or a film of III-nitride. The substrate can comprise an initial semi-polar III-nitride (e.g., template) layer or epilayer grown on a substrate (e.g., heteroepitaxially on a foreign substrate, such as sapphire, spinel, or silicon carbide).

The vicinal surface can be oriented or miscut, with respect to an on-axis semi-polar plane of a semi-polar III-nitride substrate, along a direction of one or more slip planes of the semi-polar III-nitride device layers, so as to counter, counter-balance, counter-act, reduce, or eliminate the epilayer tilt caused by the slip planes.

The step can comprise misorienting a non-miscut on-axis semi-polar III-nitride substrate by an angle having a magnitude that is substantially equal to a magnitude of an angle of the epilayer tilt obtained in Block 600, but in a direction that is opposite to a direction of the epilayer tilt obtained in Block 600, to form the vicinal surface of the semi-polar III-nitride substrate.

The miscut can comprise an intentional miscut, e.g., a surface intentionally polished/cut/sliced at a miscut angle with respect to the on-axis semipolar surface of the substrate. The miscut can comprise fabricating or mechanically modifying the underlying substrate, e.g., forming a fabricated miscut.

The miscut can be towards the c+/c− axis of the III-nitride device layers to compensate for the tilt.

For example, the vicinal surface can be oriented or miscut at an angle with respect to a semipolar plane of the III-nitride substrate, towards a c+ or c− direction of the III-nitride substrate, wherein the angle is sufficiently small that the device layers grown on the III-nitride substrate are semipolar (e.g., maintain a semipolar property that is characteristic of/similar to/the same as the semi-polar plane of the III-nitride substrate). For example, the angle can be 5 degrees or less.

For example, if the III-nitride device layers are tensile strained films (or under tensile stress), then the miscut/orientation can be towards the c+/− axis of the device layers/substrate, but in an opposite direction than if the III-nitride device layers are compressively strained (or under compressive stress).

An orientation of the vicinal surface can be selected depending on a thickness and/or composition of the device layers, and/or a non-miscut on-axis semi-polar orientation of the semi-polar III-nitride substrate.

For example, the on-axis semi-polar surface of the semi-polar III-nitride substrate can be angled at 60 degrees or more from a c-plane of the on-axis semi-polar III-nitride substrate. The vicinal surface can be oriented by more than 0 degrees and less than 5 degrees, in a c+ or c− direction, from the on-axis semi-polar surface of a GaN substrate. In another example, the device layers can be (Al,In)GaN layers on a GaN substrate, wherein the vicinal surface is oriented in a range of 0.2 to 1 degrees, in a c+ or c− direction, from a (1-122) plane of a (1-122) GaN substrate. In yet another example, the device layers can be (Al,In)GaN layers on a GaN substrate, wherein the vicinal surface is oriented by more than 0 degrees in a c+ or c− direction from a (20-21) plane of a (20-21) GaN substrate.

### Device Layer Growth

Block 604 of FIG. 6 represents growing the III-nitride semi-polar device layers on the vicinal surface. The growing can include growing device layers on the vicinal substrate to fabricate an electronic or optoelectronic device, including a light emitting diode, a transistor, a solar cell, or a laser diode.

The semi-polar III-nitride device layers can comprise layers that are non-coherently grown or that are partially or fully relaxed. For a layer X grown on a layer Y, for the case of coherent growth, the in-plane lattice constant(s) of X are constrained to be the same as the underlying layer Y. If X is fully relaxed, then the lattice constants of X assume their natural (i.e. in the absence of any strain) value. If X is neither coherent nor fully relaxed with respect to Y, then it is considered to be partially relaxed. In some cases, the substrate might have some residual strain.

The III-nitride semi-polar device layers on the vicinal surface can have reduced or eliminated epilayer tilt as compared to semi-polar III-nitride device layers that are grown on a different vicinal surface. The III-nitride semi-polar device layers on the vicinal surface can have reduced or eliminated epilayer tilt as compared to semi-polar III-nitride device layers that are grown on an on-axis semi-polar surface of the semi-polar III-nitride substrate or epilayer.

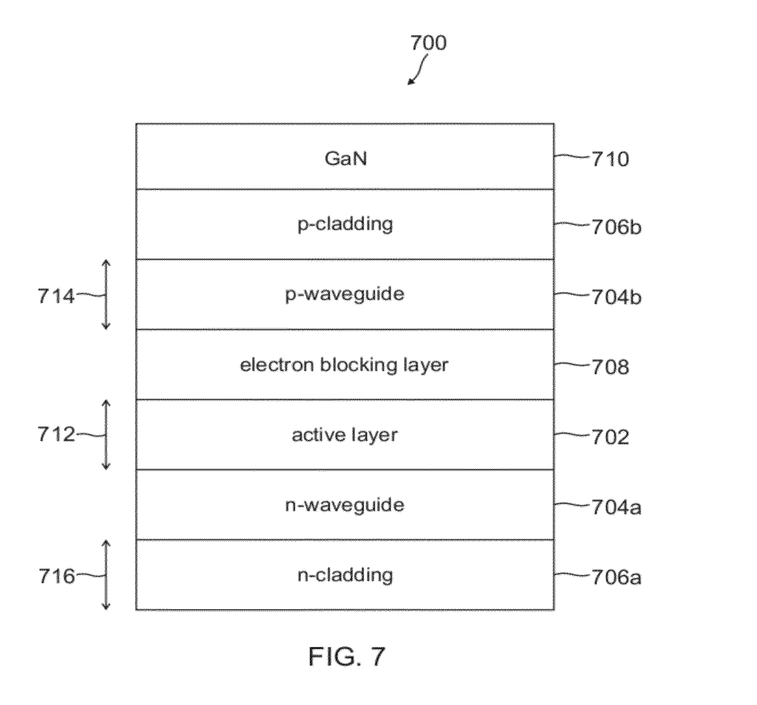

The III-nitride semi-polar device layers deposited on the vicinal surface (e.g., 402 in FIG. 4) can form a semi-polar III-nitride light emitting device structure 700, as shown in FIG. 7. FIG. 7 illustrates a device structure 700 including one or more semi-polar light emitting active layers 702 that emit light (or electromagnetic radiation) having a peak intensity at a wavelength in a green wavelength range or longer (e.g., red or yellow light), or a peak intensity at a wavelength of 500 nm or longer. However, the present invention is not limited to devices emitting at particular wavelengths, and the devices can emit at other wavelengths. For example, the present invention is applicable to blue, yellow, and red light emitting devices.

The semi-polar III-nitride active layers 702 can be sufficiently thick, and have sufficiently high Indium composition, such that the light emitting device emits the light having the desired wavelengths.

The light emitting active layer(s) 702 can include Indium containing layers, such as InGaN layers (e.g., one or more InGaN quantum wells with GaN barriers). The InGaN quantum wells can have an Indium composition of at least 7%, at least 10%, at least 16%, or at least 30%, and a thickness greater than 4 nanometers (e.g., 5 nm), at least 5 nm, or at least 8 nm, for example. However, the quantum well thickness can also be less than 4 nm, although it is typically above 2 nm thickness.

The semi-polar light emitting device structure 700 can comprise an LED or LD device structure, wherein the III-nitride semi-polar device layers further include n-type waveguiding layers 704a and p-type waveguiding layers 704b (and/or n-type cladding layers 706a and p-type cladding layers 706b) that are sufficiently thick, and have a composition, to function as waveguiding/cladding layers for the light emitted by the active layers 702 of the LD or LED.

The waveguiding layers 704a-b can have an Indium composition of at least 7% or at least 30%, for example.

The waveguiding layers 704a-b can comprise one or more InGaN quantum wells with GaN barrier layers, and the cladding layers 706a-b can comprise one or more periods of alternating AlGaN and GaN layers, for example. However, the device structure can be AlGaN cladding layer free.

The device structure can further comprise an AlGaN blocking layer 708 and a GaN layer 710. While FIG. 7 illustrates a Laser Diode structure, the structure can be modified as necessary to form a Light Emitting Diode structure.

One or more of the III-nitride semi-polar device layers (e.g., 702, 704a-b, 706a-b), can be heterostructures, or layers that are lattice mismatched with, and/or have a different composition from, another of the semi-polar III-nitride layers, or the substrate. For example, the device layers can be (Al,In)GaN layers on a GaN substrate. The device layers can include InGaN layer(s) and an AlGaN layer(s), wherein the heterointerface is between the InGaN layer and the AlGaN layer, between the InGaN layer and a GaN layer, or between an AlGaN layer and a GaN layer.

Block 606 of FIG. 6 represents processing, and/or contacting the device layers on the vicinal substrate to fabricate any electronic or optoelectronic device, including, but not limited to, an LED, a transistor, a solar cell, or a LD.

One or more steps of FIG. 6 can be omitted, as desired. Additional steps can also be included.

Device Layer Properties

The vicinal surface 402 can result in one or more of the following: uniform thickness, uniform composition, uniform doping, uniform electrical properties, and uniform luminescence, across an entire surface area of one or more of the device layers (e.g., 702, 704a-b, 706a-b, 710).

The vicinal surface can control surface morphology of the (e.g., epitaxial) device layers (e.g., 702, 704a-b, 706a-b, 710). An orientation of the vicinal surface 402 can be such the III-nitride semi-polar device layers grow in a planar growth mode on the vicinal surface 402, resulting in a planar top surface of the semi-polar III-nitride device layers. A surface roughness of the top surface can be less than 0.4 nanometers over an area of at least 5 micrometers by 5 micrometers of the top surface. The surface roughness can be less than or equal to the surface roughness of the surface illustrated in FIG. 3(a). An orientation of the vicinal surface can remove, minimize, or reduce slip related surface steps, or shear stress related features, from a top surface of the III-nitride semi-polar device layers or device structure (e.g., remove or reduce surface features resulting from an epilayer tilt equal to, less than, or greater than 0.66, for example).

For example, the vicinal surface can be such that a top surface of the light emitting device structure emits light with an emission that is uniform over an area of the top surface of at least 20 micrometers by 20 micrometers (e.g, light emission can be at least as uniform as illustrated in FIG. 3(a)).

Device Layer Thickness

One or more of the semi-polar III-nitride device layers (e.g., 702, 704a-b, 706a-b) can have a thickness equal to or greater than a critical thickness for the one or more III-nitride layers.

The equilibrium critical thickness corresponds to the case when it is energetically favorable to form one misfit dislocation at the layer/substrate interface.

Experimental, or kinetic critical thickness, is always somewhat or significantly larger than the equilibrium critical thickness. However, regardless of whether the critical thickness is the equilibrium or kinetic critical thickness, the critical thickness corresponds to the thickness where a layer transforms from fully coherent to partially relaxed.

Another example of critical thickness is the Matthews Blakeslee critical thickness [9].

A total thickness 712 of all the active layers 702 (e.g., multi-quantum-well stack thickness) can be equal to, or greater than, the critical thickness for the active layers. A total thickness 714 of the n-type waveguiding layers 704a (or p-type waveguiding layers 704b) can be equal to, or greater than, the critical thickness for the n-type waveguiding layers 704a (or the p-type waveguiding layers 704b, respectively). A total thickness 716 of the n-type cladding layers 706a (or p-type cladding layers 706b) can be equal to, or greater than, the critical thickness for the n-type cladding layers 706a (or the p-type cladding layers 706b, respectively).

One or more of the device layers (e.g., 702, 704a-b, 706a-b) can have a thickness and/or composition that is high enough such that a film, comprising all or one or more of the device layers, has a thickness near or greater than the film's critical thickness for relaxation. The device layers can comprise layers that are non-coherently grown or that are partially or fully relaxed.

One or more of the semipolar III-nitride device layers (e.g., 702, 704a-b, 706a-b) can be thicker, and have a higher alloy composition (e.g., more Al, In, and/or B, or non-gallium element), as compared to semi-polar III-nitride device layers that are grown on an on-axis surface, or different vicinal surface, of a semi-polar III-nitride substrate or epilayer.

Possible Modifications

The present invention includes the following modifications:
Different substrate growth techniques, including, but not limited to, Hydride Vapor Phase Epitaxy (HVPE), Metal Organic Chemical Vapor Deposition (MOCVD), Molecular Beam Epitaxy (MBE), Vapor Phase Epitaxy (VPE), or ammonothermal growth techniques.
Different polishing/slicing/etching/surface preparation techniques.
Instead of the substrate, homo/heteroepitaxial thin films could be miscut. The thin films could be on foreign substrates, for example.
The heteroepitaxial films could be partially or fully relaxed.
Use of slip systems other than the basal (0001) slip system. If slip systems other than the basal (0001) slip system are involved, the direction of the tilt and consequently the compensating miscut would change.

Advantages and Improvements

Controlling surface morphology through varying substrate vicinality can significantly alter optical/electrical device performance and/or yield [3-7]. Improved surface morphology can lead to a number of advantages for semipolar nitride device manufacturers, including, but not limited to, better uniformity in the thickness, composition, doping, electrical properties, and luminescence characteristics of individual layers in a given device. Furthermore, smooth surfaces can be especially beneficial for semipolar nitride laser diodes, leading to significant reductions in optical scattering losses.

An advantage of the devices fabricated using this method would be the ability to tailor vicinality of the device's epitaxial layers.

The present invention can be used to fabricate semipolar III-nitride based optoelectronic/electronic devices, e.g., light emitting diodes (LEDs), laser diodes (LDs), photovoltaic or solar cells, transistors, and High Electron Mobility Transistors (HEMTs), etc.

### REFERENCES

The following references are incorporated by reference herein.
[1] Tyagi et al., Applied Physics Letters 95, 251905 (2009).
[2] Young et al., Applied Physics Express 3, 011004 (2010).
[3] U.S. Utility patent application Ser. No. 12/716,176, filed Mar. 2, 2010, by Robert M. Farrell, Michael Iza, James S. Speck, Steven P. DenBaars and Shuji Nakamura, entitled “METHOD OF IMPROVING SURFACE MORPHOLOGY OF (Ga,Al,In,B)N THIN FILMS AND DEVICES GROWN ON NONPOLAR OR SEMIPOLAR (Ga,Al,In,B)N SUBSTRATES,” attorney' docket number 30794.306-US-U1 (2009-429).
[4] Lin et al., Applied Physics Express 2, 082102 (2009).
[5] Perlin et al., Physica Status Solidi-A 206, 1130 (2009).
[6] Tachibana et al., Physica Status Solidi-C 3, 1819 (2006).
[7] Tachibana et al., Physica Status Solidi-C 5, 2158 (2008).
[8] Hirai et al., Applied Physics Letters 91, 191906 (2007).
[9] J. Matthews and A. Blakeslee, J. Cryst. Growth 32 265 (1976).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for fabricating a semi-polar III-nitride substrate for semi-polar III-nitride device layers, comprising:
providing a vicinal surface of a substrate, wherein:
growth of device layers on the vicinal surface compensates for epilayer tilt of the device layers caused by one or more misfit dislocations at one or more heterointerfaces with the device layers,
the substrate is a semi-polar III-nitride substrate,
the device layers are semi-polar III-nitride layers, and
the device layers are relaxed heteroepitaxial layers.

2. The method of claim 1, wherein an orientation of the vicinal surface partially or fully compensates for the epilayer tilt.

3. The method of claim 2, wherein the epilayer tilt caused by the misfit dislocations is at least 0.5 degrees.

4. The method of claim 1, further comprising growing the device layers on the vicinal surface, wherein an orientation of the vicinal surface is such the device layers grow in a planar growth mode on the vicinal surface, resulting in a planar top surface of the device layers.

5. The method of claim 4, wherein the vicinal surface is such that the top surface has a surface roughness of 0.4 nanometers or less over an area of at least 5 micrometers by 5 micrometers of the top surface.

6. The method of claim 1, wherein an orientation of the vicinal surface removes, minimizes, or reduces slip related or shear stress related features from a top surface of the device layers.

7. The method of claim 1, wherein the device layers are thicker and higher composition alloy epilayers as compared to:
semi-polar III-nitride device layers that are grown on an on-axis surface of the semi-polar III-nitride substrate, or
semi-polar III-nitride device layers that are grown on a different vicinal surface of the semi-polar III-nitride substrate.

8. The method of claim 1, wherein the device layers:
form a semi-polar III-nitride light emitting device structure,
include one or more light emitting active layers that emit light having a peak intensity at a wavelength in a green wavelength range or longer, or emit light having a peak intensity at a wavelength of 500 nm or longer, and
contain Indium.

9. The method of claim 8, wherein:
the semi-polar III-nitride light emitting device structure comprises a Light Emitting Diode (LED) or Laser Diode (LD) device structure,
the device layers further include waveguiding layers that are sufficiently thick, and have a composition, to function as waveguiding layers for the light emitted by the active layers of the LD or LED, or
the device layers further include waveguiding and cladding layers that are sufficiently thick, and have a composition, to function as waveguiding and cladding layers for the LD or LED.

10. The method of claim 9, wherein the active layers and waveguiding layers comprise one or more InGaN quantum wells with GaN barrier layers, and the cladding layers comprise one or more periods of alternating AlGaN and GaN layers.

11. The method of claim 9, wherein the vicinal surface is such that a top surface of the semi-polar III-nitride light emitting device structure emits the light with an emission that is uniform over an area of the top surface of at least 20 micrometers by 20 micrometers.

12. The method of claim 9, wherein one or more device layers are heterostructures, or lattice mismatched with another of the device layers or the substrate, or comprise a different composition from another of the device layers or the substrate.

13. The method of claim 1, wherein one or more of the device layers have a thickness and composition that is high enough such that a film, comprising the device layers, has a thickness near or greater than the film's critical thickness for relaxation.

14. The method of claim 1, wherein the device layers comprise layers that are non-coherently grown or that are partially or fully relaxed.

15. The method of claim 1, wherein the vicinal surface is oriented or miscut, with respect an on-axis semi-polar plane of the substrate, along a direction of one or more slip planes of the device layers, so as to counter or reduce the epilayer tilt caused by the slip planes.

16. The method of claim 1, wherein the vicinal surface is oriented or miscut at an angle with respect to a semipolar plane of the substrate, and towards a c+ or c− direction of the substrate, and the angle is sufficiently small that the device layers grown on the substrate have a semipolar property that is characteristic of the semi-polar plane of the substrate.

17. The method of claim 16, wherein the angle is 5 degrees or less.

18. The method of claim 1, wherein the substrate is bulk III-nitride or a film of III-nitride.

19. The method of claim 1, wherein the substrate comprises 10⁶ cm⁻² or more threading dislocations.

20. The method of claim 1, further comprising growing the device layers on the vicinal substrate to fabricate an electronic or optoelectronic device, including a light emitting diode, a transistor, a solar cell, or a laser diode.

21. A III-nitride substrate for a semipolar optoelectronic or electronic device, comprising:
a vicinal surface of a substrate, wherein:
growth of device layers on the vicinal surface compensates for epilayer tilt of the device layers caused by one or more misfit dislocations at one or more heterointerfaces with the device layers,
the substrate is a semi-polar III-nitride substrate,
the device layers are semi-polar III-nitride layers, and
the device layers are relaxed heteroepitaxial layers.

22. The substrate of claim 21, wherein an orientation of the vicinal surface partially or fully compensates for the epilayer tilt.

23. The substrate of claim 22, wherein the epilayer tilt caused by the misfit dislocations is at least 0.5 degrees.

24. The substrate of claim 21, further comprising the device layers grown into a semi-polar III-nitride device structure on the vicinal surface, wherein an orientation of the vicinal surface is such that the III-nitride device structure has a planar top surface.

25. The substrate of claim 24, further comprising a surface roughness of less than 0.4 nanometers over an area of at least 5 micrometers by 5 micrometers of the top surface.

26. The substrate of claim 21, wherein an orientation of the vicinal surface removes, minimizes, or reduces slip related or shear stress related features from a top surface of the device layers.

27. The substrate of claim 21, wherein the device layers are thicker and higher composition alloy epilayers as compared to:
semi-polar III-nitride device layers that are grown on an on-axis surface of a semi-polar III-nitride substrate, or
semi-polar III-nitride device layers that are grown on a different vicinal surface of a semi-polar III-nitride substrate.

28. The substrate of claim 21, further comprising the device layers forming a semi-polar III-nitride light emitting device structure, wherein:
the III-nitride semi-polar device layers include one or more light emitting active layers,
the light emitting active layers contain Indium, and
the light emitting active layers emit light having a peak intensity at a wavelength in a green wavelength range or longer, or emit light having a peak intensity at a wavelength of 500 nm or longer.

29. The substrate of claim 28, wherein:
the semi-polar III-nitride light emitting device structure comprises a Light Emitting Diode (LED) or Laser Diode (LD) device structure,
the device layers further include waveguiding layers that are sufficiently thick, and have a composition, to function as waveguiding layers for the light emitted by the light emitting active layers of the LD or LED, or
the device layers further include waveguiding and cladding layers that are sufficiently thick and have a composition to function as waveguiding and cladding layers for the LD or LED.

30. The substrate of claim 29, wherein the light emitting active layers and waveguiding layers comprise one or more InGaN quantum wells with GaN barrier layers, and the cladding layers comprise one or more periods of alternating AlGaN and GaN layers.

31. The substrate of claim 21, wherein:
the device layers form a semi-polar III-nitride light emitting device structure, and
the vicinal surface is such that a top surface of the semi-polar III-nitride light emitting device structure emits light with an emission that is uniform over an area of the top surface of at least 20 micrometers by 20 micrometers.

32. The substrate of claim 21, wherein one or more of the device layers are heterostructures, or lattice mismatched with another of the device layers or the substrate, or comprise a different composition from another of the device layers or the substrate.

33. The substrate of claim 21, wherein one or more of the device layers have a thickness and composition that is high enough such that a film, comprising the semi-polar III-nitride layers, has a thickness near or greater than the film's critical thickness for relaxation.

34. The substrate of claim 21, wherein the device layers comprise layers that are non-coherently grown or that are partially or fully relaxed.

35. The substrate of claim 21, wherein the vicinal surface is oriented or miscut, with respect an on-axis semi-polar plane of the substrate, along a direction of one or more slip planes of the device layers, so as to counter or reduce the epilayer tilt caused by the slip planes.

36. The substrate of claim 21, wherein the vicinal surface is oriented or miscut at an angle with respect to a semipolar plane of the substrate, and towards a c+ or c− direction of the III-nitride substrate, and the angle is sufficiently small that the semi-polar III-nitride device layers grown on the substrate have a semipolar property that is characteristic of the semi-polar plane of the substrate.

37. The substrate of claim 36, wherein the angle is 5 degrees or less.

38. The substrate of claim 21, wherein the substrate is bulk III-nitride or a film of III-nitride.

39. The substrate of claim 21, wherein the III-nitride substrate comprises 10⁶ cm⁻² or more threading dislocations.

40. The substrate of claim 21, wherein the device layers on the vicinal substrate form an electronic or optoelectronic device, including a light emitting diode, a transistor, a solar cell, or a laser diode.
